(19) United States
(12) Patent Application Publication
(10) Pub. No.: US 2015/0014852 A1
(43) Pub. Date: Jan. 15, 2015

(54) PACKAGE ASSEMBLY CONFIGURATIONS FOR MULTIPLE DIES AND ASSOCIATED TECHNIQUES

(71) Applicants: Yueli Liu, Gilbert, AZ (US); Islam A. Salama, Chandler, AZ (US); Mihir K. Roy, Chandler, AZ (US); Ram S. Viswanath, Phoenix, AZ (US)

(72) Inventors: Yueli Liu, Gilbert, AZ (US); Islam A. Salama, Chandler, AZ (US); Mihir K. Roy, Chandler, AZ (US); Ram S. Viswanath, Phoenix, AZ (US)

(21) Appl. No.: 13/941,322

(22) Filed: Jul. 12, 2013

(51) Int. Cl. H01L 23/498; H01L 23/00

(52) U.S. Cl. CPC H01L 23/49811; H01L 23/49816; H01L 24/81
USPC 257/738; 257/737; 438/108

(57) ABSTRACT

Embodiments of the present disclosure are directed towards package assembly configurations for multiple dies and associated techniques. In one embodiment, a package assembly includes a package substrate having a first side and a second side disposed opposite to the first side, a first die mounted on the first side and electrically coupled with the package substrate by one or more first die-level interconnects, a second die mounted on the second side and electrically coupled with the package substrate by one or more second die-level interconnects and package-level interconnect structures disposed on the first side of the package substrate and configured to route electrical signals between the first die and an electrical device external to the package substrate and between the second die and the external device. Other embodiments may be described and/or claimed.

### FIELD

Embodiments of the present disclosure generally relate to the field of integrated circuits, and more particularly, to package assembly configurations for multiple dies and associated techniques.

### BACKGROUND

Smaller and lighter electronics devices with greater functionality are being developed in response to demand by customers for mobile computing devices such as, for example, smartphones and tablets. Currently, the devices may include packages with dies stacked on one another. However, the cost and complexity of fabricating electrical routing for stacked dies is still very high and, thus, may not be feasible for low-cost high-volume manufacturing. Additionally, the stacked die configuration may make removal of heat from the stacked dies more challenging.

Instead of stacking the dies on one another, other package configurations may include multiple package substrates with respective dies mounted on each of the multiple substrates. For example, a substrate having a die mounted on the substrate may be coupled with another substrate having another die mounted on the other substrate. However, such configurations may have a form factor (e.g., Z-height) that is too large, a weight that is too high and/or may exhibit poor electrical performance for connections between the dies.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a cross-section side view of an example integrated circuit (IC) package assembly, in accordance with some embodiments.

FIGS. 2a-d schematically illustrate various stages of fabrication of an example IC package assembly, in accordance with some embodiments.

FIG. 3 schematically illustrates a flow diagram for a method of fabricating an IC package assembly, in accordance with some embodiments.

FIG. 4 schematically illustrates a computing device that includes an IC package assembly as described herein, in accordance with some embodiments.

### DETAILED DESCRIPTION

Embodiments of the present disclosure describe package assembly configurations for multiple dies and associated techniques. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature,” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

As used herein, the term “module” may refer to, be part of, or include an Application Specific Integrated Circuit (ASIC), an electronic circuit, a system-on-chip (SoC), a processor (shared, dedicated, or group) and/or memory (shared, dedicated, or group) that execute one or more software or firmware programs, a combinational logic circuit, and/or other suitable components that provide the described functionality.

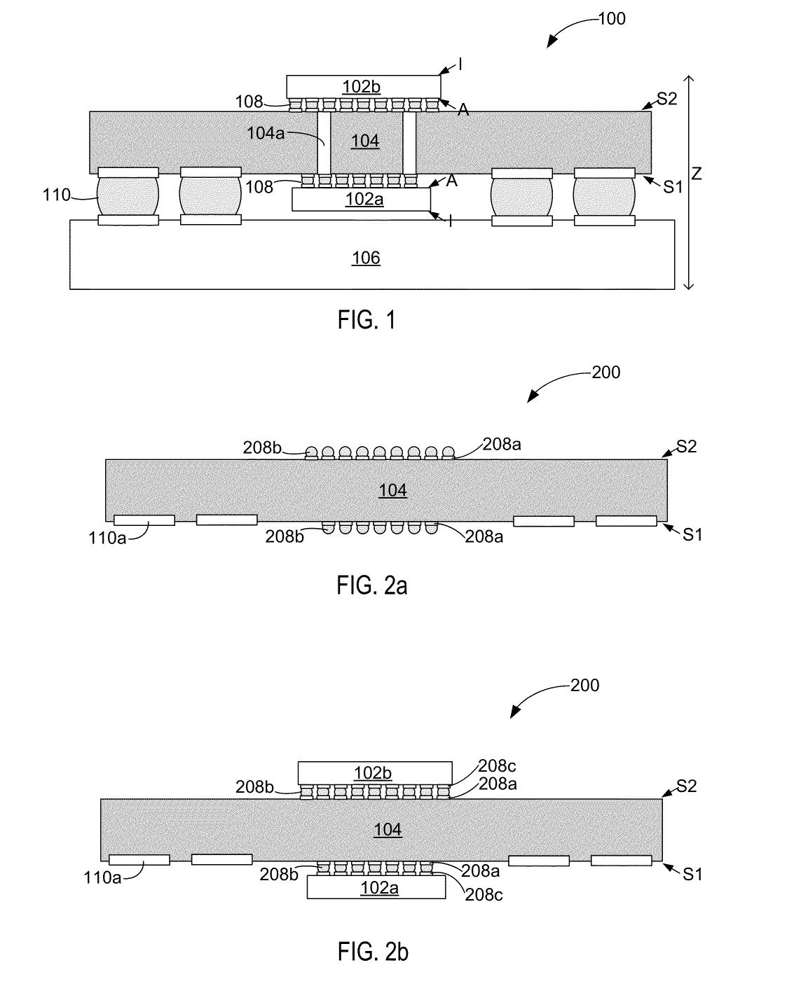

FIG. 1 schematically illustrates a cross-section side view of an example integrated circuit (IC) package assembly (hereinafter “package assembly 100”), in accordance with some embodiments. In some embodiments, the package assembly 100 includes a first die 102a and a second die 102b mounted on opposing sides of a package substrate 104. For example, in the depicted embodiment, the package substrate 104 has a first side, S1, and a second side, S2, disposed opposite to the first side S1. The first die 102a is mounted on the first side S1 and is electrically coupled with the package substrate 104 using one or more die-level interconnects 108. The second die 102b is mounted on the second side S2 and is electrically coupled with the package substrate 104 using one or more die-level interconnects 108.

In the depicted embodiment, the die-level interconnects 108 include bumps such as, for example, controlled collapse chip connection (C4) bumps that form a joint and electrical connection between pads disposed on an active side A of each of the first die 102a and the second die 102b and pads disposed on the package substrate 104, as can be seen, to provide a flip-chip configuration. In some embodiments, the die-level interconnects 108 include the pads. Active circuitry (e.g., transistor devices) may be formed on the active side A. An inactive side, I, may be disposed opposite to the active side A, as can be seen.

In other embodiments, other suitable die-level interconnects 108 may be used to couple the first die 102a and/or the second die 102b with the package substrate 104. For example, traces, pillars, and the like may be used to couple the dies 102a, 102b with the package substrate 104. In other embodiments, bonding wires may be used to couple one or both of the first die 102a and the second die 102b with the package substrate 104. In a wirebonding configuration (not shown), an inactive side of a die may coupled with the package substrate 104 using an adhesive and an active side of the die may be electrically coupled with pads or analogous structures on the package substrate 104 using bonding wires. Other suitable well-known die-level interconnect structures (e.g., first-level interconnects (FLIs)) may be used to provide die-level interconnects 108 between the dies 102a, 102b and the package substrate 104 according to various embodiments.

In some embodiments, package-level interconnects 110 may be disposed on the first side S1 of the package substrate 104. The package-level interconnects 110 (e.g., second-level interconnects (SLIs)) may be configured to route electrical signals between the dies 102a, 102b and an electrical device external to the package substrate 104 such as, for example, a circuit board 106, as can be seen. The electrical signals may include, for example, input/output (I/O) signals and/or power/ground. For example, the package substrate 104 may include electrical routing features (not shown) that are configured to route the electrical signals between each of the first die 102a and the second die 102b and corresponding interconnects of the package-level interconnects 110. The electrical routing features may include, for example, traces, trenches, vias, lands, pads or other suitable structures and may be configured in a fan-out configuration in some embodiments. As can be seen, the first die 102a may be disposed between the package substrate 104 and the circuit board 106 in some embodiments.

In the depicted embodiment, the package-level interconnects 110 include solder balls that form a joint with pads respectively disposed on the package substrate 104 and the circuit board 106, as can be seen. In some embodiments, the package-level interconnects 110 include the pads. In some embodiments, the package-level interconnects 110 may be arranged in a ball-grid array (BGA) configuration, a land-grid array (LGA) configuration, or other well-known configuration. The package-level interconnects 110 may include other suitable types of interconnect structures in other embodiments including, for example, pillars as described further herein.

In some embodiments, the package substrate 104 may include additional electrical routing features disposed between the first side S1 and the second side S2 and configured to electrically couple the dies 102a, 102b with one another. In some embodiments, the electrical routing features may include through-substrate vias (TSubVs) 104a to electrically couple the dies 102a, 102b through the package substrate 104. In some embodiments, a bulk of the package substrate 104 may include or be substantially composed of a polymer (e.g., organic material such as epoxy), ceramic, glass or semiconductor material. In one embodiment, the package substrate 104 comprises silicon and the one or more TSubVs 104a include one or more through-silicon vias (TSVs). In other embodiments, the TSubVs 104a may include other suitable structures such as, for example, plated-through holes (PTHs) or laser through holes (LTHs), which may be disposed in the package substrate 104 to route electrical signals between the dies 102a, 102b. Other suitable electrical routing features may be used to electrically couple the dies 102a, 102b in other embodiments including, for example, traces, trenches, vias, lands, pads or other well-known suitable structures.

According to various embodiments, the package substrate 104 may be a substrate of a flip-chip ball-grid array (FCBGA) or flip-chip chip scale (FCCSP) package. The package substrate 104 may comport with a variety of other well-known package configurations in other embodiments.

The first die 102a and the second die 102b may represent any of a wide variety of types of dies, according to various embodiments. For example, in some embodiments the first die 102a and/or the second die 102b may represent one or more of a logic die, memory die, processor, ASIC, system on chip (SoC) or other type of die. In some embodiments, one of the first die 102a and the second die 102b is a processor and the other of the first die 102a and the second die 102b is memory. The processor and memory may be electrically coupled together to route electrical signals between them. In some embodiments, one of the first die 102a and the second die 102b is an ASIC and the other of the first die 102a and the second die 102b is a field programmable gate array (FPGA), which dies 102a, 102b may be electrically coupled to route electrical signals between them. In some embodiments, one or both of the first die 102a and the second die 102b is a SoC or ASIC. In embodiments where both the first die 102a and the second die 102b are SoCs and/or ASICs, the dies 102a, 102b may not be electrically coupled to one another.

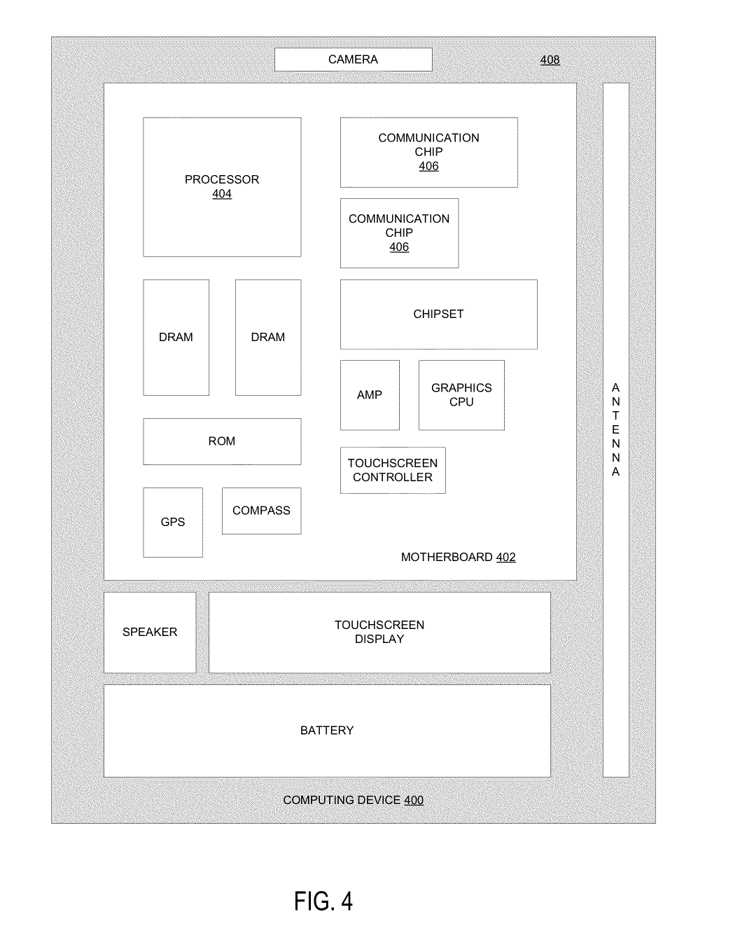

The circuit board 106 may be a printed circuit board (PCB) composed of an electrically insulative material such as an epoxy laminate. For example, the circuit board 106 may include electrically insulating layers composed of materials such as, for example, polytetrafluoroethylene, phenolic cotton paper materials such as Flame Retardant 4 (FR-4), FR-1, cotton paper and epoxy materials such as CEM-1 or CEM-3, or woven glass materials that are laminated together using an epoxy resin prepreg material. Structures (not shown) such as traces, trenches, vias, etc. may be formed through the electrically insulating layers to route the electrical signals of the dies 102a, 102b through the circuit board 106. The circuit board 106 may be composed of other suitable materials in other embodiments. In some embodiments, the circuit board 106 is a motherboard (e.g., motherboard 402 of FIG. 4).

Providing a package assembly 100 with dies 102a, 102b respectively mounted on opposing sides S1, S2 of the package substrate 104 may provide a package assembly having lower fabrication cost than a package assembly including stacked dies (e.g., dies stacked on one another). Such configuration may further reduce a Z-dimension (e.g., see arrow Z) of the package assembly relative to stacked die configurations or package-on-package (PoP) configurations where each die is mounted on a respective substrate to facilitate implementation of the package assembly into smaller electronic devices such as mobile computing devices. The double-sided die configuration of the package substrate 104 may further reduce a weight by eliminating a substrate for one of the dies 102a, 102b relative to some PoP configurations. Additionally, providing dies 102a, 102b on opposing sides of the substrate 104 (e.g., as depicted in package assembly 100) may increase electrical performance by providing shorter, lower resistance and/or improved silicon efficiency for the electrical connection between the dies 102a, 102b relative to other package configurations. Such configuration may further facilitate heat removal from each of the dies 102a, 102b relative to stacked configurations of the dies.

The package assembly 100 may include more dies than depicted. For example, in some embodiments, the package assembly 100 may further include one or more dies coupled with the first side S1 and/or the second side S2 of the package substrate in a side-by-side configuration with one or both of the dies 102a, 102b. In some embodiments, the package assembly 100 may further include one or more dies stacked on one or both of the dies 102a, 102b and coupled with the dies 102a and/or 102b using TSVs. The package assembly 100 may include another package substrate coupled with the package substrate 104 in a PoP configuration. One or more of the dies 102a and/or 102b may be embedded in the package substrate 104. The package assembly 100 may include other suitable configurations.

The package assembly 100 may include other additional components and/or may be configured in a wide variety of other suitable configurations in other embodiments including, for example, suitable combinations of flip-chip and/or wire-bonding configurations, use of interposers, multi-chip package configurations including system-in-package (SiP) and/PoP configurations. The package assembly 100 may include suitable combinations of the embodiments described herein.

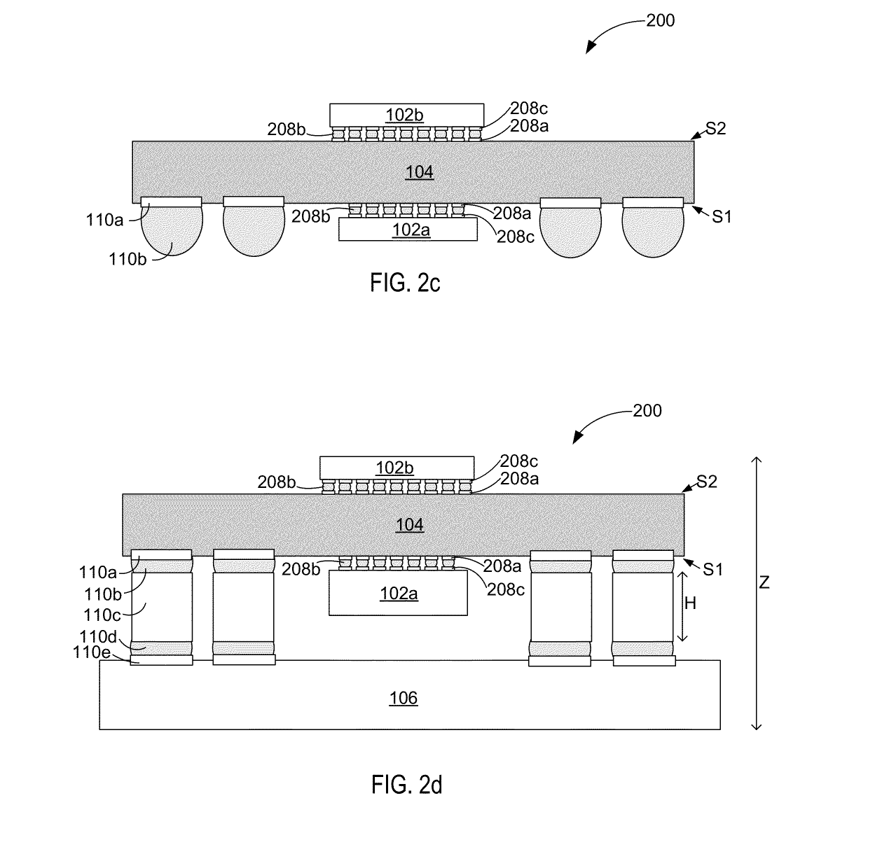

FIGS. 2a-d schematically illustrate various stages of fabrication of an example IC package assembly (hereinafter “package assembly 200”), in accordance with some embodiments. The package assembly 200 may comport with embodiments described in connection with the package assembly 100.

In FIG. 2a, a package assembly 200 is depicted subsequent to forming die-level interconnect structures on a first side S1 and second side S2 of a package substrate 104 and forming package-level interconnects on the first side S1 of the package substrate 104. In the depicted embodiment, the die-level interconnect structures include pads 208a disposed on the package substrate 104 and bumps 208b such as, for example, C4 bumps disposed on the pads 208a, as can be seen. The die-level interconnect structures on the first side S1 may be configured to receive electrical connections of a first die (e.g., first die 102a of FIG. 2b) and the die-level interconnect structures on the second side S2 may be configured to receive electrical connections of a second die (e.g., second die 102b of FIG. 2b). In other embodiments, the die-level interconnect structures on the first side S1 and/or the second side S2 may include only the pads 208a and the bumps 208b may be formed on the first die and/or the second die instead of on the package substrate 104. In some embodiments, the pads 208a may be configured to receive wirebonding connections or may represent other structures such as pillars that may be used as die-level interconnect structures.

The package-level interconnect structures on the first side S1 may include pads 110a or analogous structures that are configured to route electrical signals between the die-level interconnect structures and an electrical device external to the package substrate 104. The pads 110a may be configured to receive solder balls or pillars (e.g., copper pillars), or combinations thereof. The die-level interconnect structures and the package-level interconnect structures may be formed independently from one another in any order and/or simultaneously. For example, the pads 208a and 110a may be simultaneously formed in some embodiments using any suitable technique. Solderable material may be deposited on the pads 208a using any suitable technique to form the bumps 208b.

In FIG. 2b, the package assembly 200 is depicted subsequent to coupling a first die 102a with the first side S1 and coupling a second die 102b with the second side S2 of the package substrate 104 using the respective die-level interconnects (e.g., pads 208a and/or bumps 208b) disposed on the first side S1 and the second side S2 of the package substrate 104.

Attachment of the dies 102a, 102b may occur in any suitable order. For example, one of the first die 102a and the second die 102b may be coupled with the package substrate 104 and subsequently the other of the first die 102 and the second die 102b may be coupled with the package substrate 104. In the depicted embodiment, the dies 102a, 102b may be attached to the package substrate 104 using a solder reflow process to form a joint between the solderable material between the pads 208a on the package substrate 104 and corresponding pads 208c on the dies 102a, 102b. In other embodiments, one or both of the dies (e.g., 102a, 102b) may be attached the package substrate 104 using an adhesive to couple an inactive side of the die(s) to the package substrate 104 and bonding wires may be formed to attach electrical contacts (e.g., pads) on the active side of the die(s) with corresponding contacts (e.g., pads) on the package substrate 104.

In FIG. 2c, the package assembly 200 is depicted subsequent to coupling solder balls 110b with the pads 110a. The solder balls 110b may be coupled with the pads 110a using, for example, a solder reflow process to form a joint between the solder balls 110b and the pads 110a. The solder balls 110b coupled with the pads 110a may form BGA structures in some embodiments. Other suitable techniques may be used to form other well-known structures such as, for example, LGA structures, in other embodiments.

In some embodiments, the package assembly 200 may be ready for surface mount on a circuit board (e.g., circuit board 106 of FIG. 1) such as a motherboard using any suitable Surface Mount Technology (SMT) to provide a package assembly 100 as depicted in FIG. 1. In other embodiments, the solder balls 110b may represent solderable material deposited on the pads 110a to facilitate formation of pillar interconnect structures as described further in connection with FIG. 2d.

In FIG. 2d, the package assembly 200 is depicted subsequent to forming pillar interconnect structures to couple the package substrate 104 with the circuit board 106. The pillar interconnect structures may be formed, for example, by placing a pillar 110c (e.g., a copper pillar or other suitable material pillar) in solderable contact with the solderable material of the solder ball 110b and performing a solder reflow process to form a joint between the pillar 110c and the pad 110a. The pillar 110c may be positioned in solderable contact with solderable material 110d that is disposed on pads 110e of the circuit board 106 and a solder reflow process may be performed to form a joint between the pillar 110c and the pad 110e. In some embodiments, multiple solder reflow processes may be performed to form the pillar interconnect structures. Other suitable techniques may be used to form the pillar interconnect structures. The pillar 110c may have a height, H, that is designed or selected to provide a gap between the package substrate 104 and the circuit board 106 to accommodate a dimension of the first die 102a in the Z-dimension.

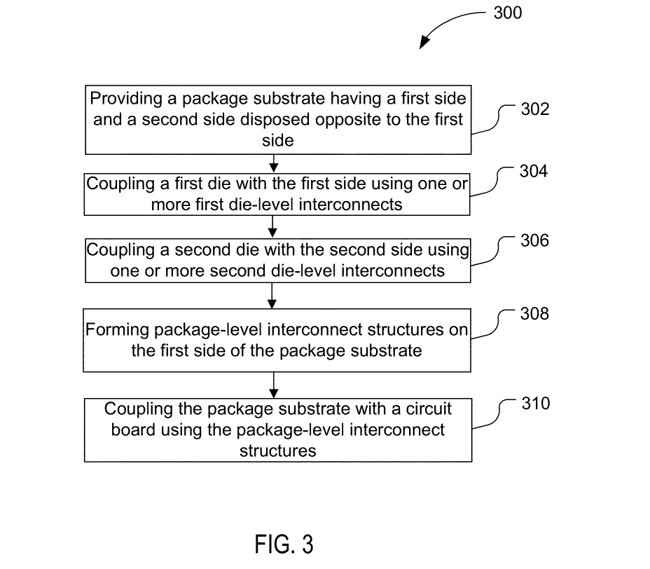

FIG. 3 schematically illustrates a flow diagram for a method 300 of fabricating an IC package assembly, in accordance with some embodiments. The method 300 may comport with embodiments described in connection with FIGS. 1-2.

At 302, the method 300 may include providing a package substrate (e.g., package substrate 104 of FIG. 2a) having a first side (e.g., side S1 of FIG. 2a) and a second side (e.g., side S2 of FIG. 2a) disposed opposite the first side. The package substrate may include electrical routing features (e.g., TSubVs 104a of FIG. 1) between the first side and the second side of the package substrate to route electrical signals between a first die and a second die.

At 304, the method 300 may include coupling a first die (e.g., first die 102a of FIG. 2b) with the first side using one or more first die-level interconnects (e.g., pads 208a and/or bumps 208b on side S1 of FIG. 2b). The first die-level interconnects may be formed in accordance with techniques described in connection with FIG. 2b and the first die may be coupled with the first side using techniques described in connection with FIG. 2b.

At 306, the method 300 may include coupling a second die (e.g., second die 102b of FIG. 2b) with the second side using one or more second die-level interconnects (e.g., pads 208a and/or bumps 208b on side S2 of FIG. 2b). The second die-level interconnects may be formed in accordance with techniques described in connection with FIG. 2b and the second die may be coupled with the second side using techniques described in connection with FIG. 2b. In some embodiments, coupling the first die at 304 or coupling the second die at 304 may include forming C4 bumps or wirebond connections.

At 308, the method 300 may include forming package-level interconnect structures (e.g., pads 110a and/or solder balls 110b of FIG. 2c) on the first side of the package substrate. In some embodiments, forming the package-level interconnect structures may include forming BGA or LGA structures. In other embodiments, forming the package-level interconnect structures may include forming pillar interconnect structures (e.g., pillar 110c of FIG. 2d).

At 310, the method may include coupling the package substrate with a circuit board (e.g., circuit board 106 of FIG. 1) using the package-level interconnect structures. For example, in an embodiment where the package substrate includes solderable material, a solder reflow process may be used to form a joint between the solderable material and pads on the package substrate and circuit board.

Various operations are described as multiple discrete operations in turn, in a manner that is most helpful in understanding the claimed subject matter. However, the order of description should not be construed as to imply that these operations are necessarily order dependent. For example, actions of the method 300 be performed in another suitable order than depicted.

Embodiments of the present disclosure may be implemented into a system using any suitable hardware and/or software to configure as desired. FIG. 4 schematically illustrates a computing device 400 that includes an IC package assembly (e.g., package assembly 100 of FIG. 1) as described herein, in accordance with some embodiments. The computing device 400 may house a board such as motherboard 402 (e.g., in housing 408). The motherboard 402 may include a number of components, including but not limited to a processor 404 and at least one communication chip 406. The processor 404 may be physically and electrically coupled to the motherboard 402. In some implementations, the at least one communication chip 406 may also be physically and electrically coupled to the motherboard 402. In further implementations, the communication chip 406 may be part of the processor 404.

Depending on its applications, computing device 400 may include other components that may or may not be physically and electrically coupled to the motherboard 402. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

The communication chip 406 may enable wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. The communication chip 406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 406 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 406 may operate in accordance with other wireless protocols in other embodiments.

The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

The processor 404 of the computing device 400 may be packaged in an IC package assembly (e.g., package assembly 100 of FIG. 1) as described herein. For example, the circuit board 106 of FIG. 1 may be a motherboard 402 and the processor 404 may be a first die 102a or second die 102b mounted on a package substrate 104 of FIG. 1. The package substrate 104 and the motherboard 402 may be coupled together using package-level interconnect structures 110. The term “processor” may refer to any device or portion of a device that processes electronic data from registers and/or memory to transform that electronic data into other electronic data that may be stored in registers and/or memory.

The communication chip 406 may also include a die (e.g., first die 102a or second die 102b of FIG. 1) that may be packaged in an IC package assembly (e.g., package assembly 100 of FIG. 1) as described herein. In further implementations, another component (e.g., memory device or other integrated circuit device) housed within the computing device 400 may include a die (e.g., first die 102a or second die 102b of FIG. 1) that may be packaged in an IC package assembly (e.g., package assembly 100 of FIG. 1) as described herein.

In various implementations, the computing device 400 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. The computing device 400 may be a mobile computing device in some embodiments. In further implementations, the computing device 400 may be any other electronic device that processes data.

### EXAMPLES

According to various embodiments, the present disclosure describes an apparatus (e.g., a package assembly) comprising a package substrate having a first side and a second side disposed opposite to the first side, a first die mounted on the first side and electrically coupled with the package substrate by one or more first die-level interconnects, a second die mounted on the second side and electrically coupled with the package substrate by one or more second die-level interconnects and package-level interconnect structures disposed on the first side of the package substrate and configured to route electrical signals between the first die and an electrical device external to the package substrate and between the second die and the external device. In some embodiments, the package substrate includes electrical routing features configured to route electrical signals between the first die and the second die.

In some embodiments, the package substrate comprises a polymer, glass, semiconductor or ceramic material and the electrical routing features include one or more through substrate vias (TSubVs). In some embodiments, the package substrate comprises silicon and the one or more TSubVs include one or more through-silicon vias (TSVs). In some embodiments, the first die-level interconnects and the second die-level interconnects comprise controlled collapse chip connection (C4) bumps. In some embodiments, the package substrate is a substrate of a flip-chip ball-grid array (FCBGA) package or flip-chip chip scale (FCCSP) package and at least one of the first die and the second die is a system on a chip (SoC) die. In some embodiments, the package-level interconnects include pads. In some embodiments, the package-level interconnects include solder balls coupled with the pads. In some embodiments, the package-level interconnects include copper pillars coupled with the pads.

According to various embodiments, the present disclosure describes another apparatus (e.g., a package substrate) comprising a first side, a second side disposed opposite to the first side, one or more first die-level interconnect structures disposed on the first side, the first die-level interconnect structures being configured to receive electrical connections of a first die to be mounted on the first side, one or more second die-level interconnect structures disposed on the second side, the second die-level interconnect structures being configured to receive electrical connections of a second die to be mounted on the second side, and package-level interconnect structures disposed on the first side of the package substrate and configured to route electrical signals between the first die-level interconnect structures and an electrical device external to the package substrate and between the second die-level interconnect structures and the external device. In some embodiments, the package substrate may further include electrical routing features configured to route electrical signals between the first die-level interconnect structures and the second die-level interconnect structures. In some embodiments, the first die-level interconnect structures and the second die-level interconnect structures include pads configured to receive controlled collapse chip connection (C4) bumps or wirebond connections. In some embodiments, the package-level interconnect structures include pads configured to receive solder balls or copper pillars.

According to various embodiments, the present disclosure describes a method of fabricating a package assembly comprising providing a package substrate having a first side and a second side disposed opposite to the first side, coupling a first die with the first side using one or more first die-level interconnects, coupling a second die with the second side using one or more second die-level interconnects and forming package-level interconnect structures on the first side of the package substrate, wherein the package-level interconnect structures are configured to route electrical signals between the first die and an electrical device external to the package substrate and between the second die and the external device. In some embodiments, providing a package substrate comprises providing a package substrate including electrical routing features configured to route electrical signals between the first die and the second die.

In some embodiments, coupling the first die or coupling the second die comprises forming controlled collapse chip connection (C4) bumps. In some embodiments, coupling the first die or coupling the second die comprises forming wirebond connections. In some embodiments, forming package-level interconnect structures comprises forming ball-grid array (BGA) or land-grid array (LGA) structures. In some embodiments, forming package-level interconnect structures comprises forming pillar interconnect structures. In some embodiments, the external device is a circuit board, the method further comprising coupling the package substrate with the circuit board using the package-level interconnect structures.

According to various embodiments, the present disclosure describes a system (e.g., a computing device) comprising a package assembly including a package substrate having a first side and a second side disposed opposite to the first side, a first die mounted on the first side using one or more first die-level interconnects, a second die mounted on the second side using one or more second die-level interconnects, and package-level interconnect structures disposed on the first side of the package substrate and configured to route electrical signals between the first die and an electrical device external to the package substrate and between the second die and the external device and a circuit board, wherein the package assembly is coupled with the circuit board using the package-level interconnect structures and the first die is disposed between the first side of the package substrate and the circuit board. In some embodiments, the computing device is a mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

What is claimed is:

1. A package assembly comprising:
a package substrate having a first side and a second side disposed opposite to the first side;
a first die mounted on the first side and electrically coupled with the package substrate by one or more first die-level interconnects;
a second die mounted on the second side and electrically coupled with the package substrate by one or more second die-level interconnects; and
package-level interconnect structures disposed on the first side of the package substrate and configured to route electrical signals between the first die and an electrical device external to the package substrate and between the second die and the external device.

2. The package assembly of claim 1, wherein the package substrate includes electrical routing features configured to route electrical signals between the first die and the second die.

3. The package assembly of claim 2, wherein:
the package substrate comprises a polymer, glass, semiconductor or ceramic material; and
the electrical routing features include one or more through substrate vias (TSubVs).

4. The package assembly of claim 3, wherein:
the package substrate comprises silicon; and
the one or more TSubVs include one or more through-silicon vias (TSVs).

5. The package assembly of claim 1, wherein the first die-level interconnects and the second die-level interconnects comprise controlled collapse chip connection (C4) bumps.

6. The package assembly of claim 1, wherein:
the package substrate is a substrate of a flip-chip ball-grid array (FCBGA) package or flip-chip chip scale (FCCSP) package; and
at least one of the first die and the second die is a system on a chip (SoC) die.

7. The package assembly of claim 1, wherein the package-level interconnects include pads.

8. The package assembly of claim 7, wherein the package-level interconnects include solder balls coupled with the pads.

9. The package assembly of claim 7, wherein the package-level interconnects include copper pillars coupled with the pads.

10. A package substrate, comprising:
a first side;
a second side disposed opposite to the first side;
one or more first die-level interconnect structures disposed on the first side, the first die-level interconnect structures being configured to receive electrical connections of a first die to be mounted on the first side;
one or more second die-level interconnect structures disposed on the second side, the second die-level interconnect structures being configured to receive electrical connections of a second die to be mounted on the second side;
and package-level interconnect structures disposed on the first side of the package substrate and configured to route electrical signals between the first die-level interconnect structures and an electrical device external to the package substrate and between the second die-level interconnect structures and the external device.

11. The package substrate of claim 10, further comprising:
electrical routing features configured to route electrical signals between the first die-level interconnect structures and the second die-level interconnect structures.

12. The package substrate of claim 10, wherein the first die-level interconnect structures and the second die-level interconnect structures include pads configured to receive controlled collapse chip connection (C4) bumps or wirebond connections.

13. The package substrate of claim 10, wherein the package-level interconnect structures include pads configured to receive solder balls or copper pillars.

14. A method of fabricating a package assembly comprising:
providing a package substrate having a first side and a second side disposed opposite to the first side;
coupling a first die with the first side using one or more first die-level interconnects;
coupling a second die with the second side using one or more second die-level interconnects; and
forming package-level interconnect structures on the first side of the package substrate, wherein the package-level interconnect structures are configured to route electrical signals between the first die and an electrical device external to the package substrate and between the second die and the external device.

15. The method of claim 14, wherein providing a package substrate comprises providing a package substrate including electrical routing features configured to route electrical signals between the first die and the second die.

16. The method of claim 14, wherein coupling the first die or coupling the second die comprises forming controlled collapse chip connection (C4) bumps.

17. The method of claim 14, wherein coupling the first die or coupling the second die comprises forming wirebond connections.

18. The method of claim 14, wherein forming package-level interconnect structures comprises forming ball-grid array (BGA) or land-grid array (LGA) structures.

19. The method of claim 14, wherein forming package-level interconnect structures comprises forming pillar interconnect structures.

20. The method of claim 14, wherein the external device is a circuit board, the method further comprising:
coupling the package substrate with the circuit board using the package-level interconnect structures.

21. A computing device comprising:
a package assembly including
a package substrate having a first side and a second side disposed opposite to the first side,
a first die mounted on the first side using one or more first die-level interconnects,
a second die mounted on the second side using one or more second die-level interconnects, and
package-level interconnect structures disposed on the first side of the package substrate and configured to route electrical signals between the first die and an electrical device external to the package substrate and between the second die and the external device; and
a circuit board, wherein the package assembly is coupled with the circuit board using the package-level interconnect structures and the first die is disposed between the first side of the package substrate and the circuit board.

22. The computing device of claim 21, wherein:
the computing device is a mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.
